(19) United States
(12) Patent Application Publication
(10) Pub. No.: US 2023/0204785 A1
(43) Pub. Date: Jun. 29, 2023

(54) THERMOELECTRIC COOLER (TEC) ASSEMBLY AND FOR LASER MODULE

(71) Applicant: Beijing Voyager Technology Co., Ltd., Beijing (CN)

(72) Inventors: Yu-Ching Yeh, Fremont, CA (US); Yue Lu, Fremont, CA (US); Henghui Jiang, Fremont, CA (US)

(73) Assignee: Beijing Voyager Technology Co., Ltd., Beijing (CN)

(21) Appl. No.: 17/563,258

(22) Filed: Dec. 28, 2021

(51) Int. Cl. G01S 17/931; G01S 17/86; H01L 35/30

(52) U.S. Cl. CPC G01S 17/931; G01S 17/86; H01L 35/30

(57) ABSTRACT

An assembly for a light detection and ranging (LiDAR) system including a light source configured to provide a light beam; light collimator lens configured to collimate the light beam; an active thermal control element having an upper surface; a thermally conductive mechanical structure fixed to the upper surface of the active thermal control element thermal element, the mechanical structure being in thermal contact with the light source, the light collimator lens and the active thermal control element; a temperature sensor configured to detect the temperature of the light source; and a temperature controller configured to receive the detected temperature from the light source and in response control the temperature of the active thermal control element, which controls the temperatures of the light source and collimator lens to the same temperature via the thermally conductive mechanical structure.

### TECHNICAL FIELD

The present disclosure relates to a Light Detection and Ranging (LiDAR) system, and more particularly to using active temperature control to stabilize a LiDAR system while minimizing optical misalignment over a large ambient operating temperature range of the LiDAR system.

### BACKGROUND

LiDAR systems have been widely used in autonomous driving and producing high-definition maps. A LiDAR system may be carried by a vehicle (e.g., an automobile or an unmanned aerial vehicle) to determine the vehicle’s relative position, speed, and direction with respect to other objects or environmental features. A LiDAR system is an active remote sensing system that uses light beams to detect objects in the ambient environment and determine the distance and/or shape of the objects. In a LiDAR system, laser diodes may be used as the light source. The light beam (e.g., a pulsed laser beam) is emitted from a transmitter to illuminate at least a portion of a target and reflected-back by the target and then captured by a receiver (e.g., a light detector). The time of flight (ToF) for the received light beam is measured to estimate the distance of the target In other words, the range of a point on a target to the LiDAR system can be determined based on the time of flight of the pulsed light beam from the transmitter to the receiver of the LiDAR system. Differences in laser return times and wavelengths can then be used to make digital three-dimensional (3-D) representations of the target. The laser light used for LiDAR scan may be ultraviolet, visible, or near infrared,

LiDAR systems operate over a wide temperature range due to the different climates that autonomous driving vehicles operate. For example, a LiDAR system for autonomous driving vehicles is used in both seasonally hot and cold climates. This temperature variation causes a large range of wavelengths for the emitted light from the laser, since the laser is highly dependent on the operating temperature. That is, the laser wavelength will change with the operating temperature. A conventional way to support a large operating temperature range is to use a wide-band optical filter at the receiver to allow more of the reflected laser pulse to pass through the receiver. However, the wide-band optical filter also allows a large amount of background light to come in, thus increasing the background noise. Thus, this approach has a significant drawback in that the large amount of background noise received by the receiver degrades the signal to noise ratio (SNR) for the LiDAR system.

In order to stabilize the laser wavelength over the large operating temperature range of the LiDAR system, an active thermal control element, i.e., a Thermoelectric Cooler (TEC), can be integrated with the laser module to stabilize the temperature of laser chip by using active thermal control. Stabilizing the laser wavelength allows for a narrow-band optical filter to be used at the receiver, instead of a wide-band optical filter, which provides the benefit of a higher SNR, since less background light is received. However, this approach of actively controlling the temperature of the laser chip may cause a temperature difference (or delta) between the laser and an optical lens in the laser module, since the optical lens is not subject to the same active temperature control by the active thermal control element. This temperature delta may cause different thermal expansion amounts for the laser and the optical lens, which causes the heights of the laser and optical lens to shift by different amounts, thereby degrading the optical alignment between the laser and optical lens in the LiDAR system.

Embodiments of the disclosure address the above problems by using active temperature control to stabilize the laser wavelength while minimizing optical misalignment over a large ambient operating temperature range of the LiDAR system.

### SUMMARY

Techniques disclosed herein may offer various improvements and advantages over existing techniques. According to certain embodiments, an assembly for a light detection and ranging (LiDAR) system may include a light source configured to provide a light beam, a light collimator lens configured to collimate the light beam, an active thermal control element having an upper surface, a thermally conductive mechanical structure fixed to the upper surface of the active thermal control element, the mechanical structure being in thermal contact with the light source, the light collimator lens and the active thermal control element, a temperature sensor configured to detect the temperature of the light source, and a temperature controller configured to receive the detected temperature from the light source and in response control the temperature of the active thermal control element.

In some embodiments, the temperature sensor may be a thermistor and the active thermal control element may be a thermoelectric cooler (TEC). In some embodiments, the light collimator lens may be a fast-axis collimating lens. In some embodiments, the light source may be fixed to an upper surface of the thermally conductive mechanical structure and the light collimator lens may be fixed to an upper surface of the thermally conductive mechanical structure.

The terms and expressions that have been employed are used as terms of description and not of limitation, and there is no intention in the use of such terms and expressions of excluding any equivalents of the features shown and described or portions thereof. It is recognized, however, that various modifications are possible within the scope of the systems and methods claimed. Thus, it should be understood that, although the present system and methods have been specifically disclosed by examples and optional features, modification and variation of the concepts herein disclosed should be recognized by those skilled in the art, and that such modifications and variations are considered to be within the scope of the systems and methods as defined by the appended claims.

This summary is not intended to identify key or essential features of the claimed subject matter, nor is it intended to be used in isolation to determine the scope of the claimed subject matter. The subject matter should be understood by reference to appropriate portions of the entire specification of this disclosure, any or all drawings, and each claim.

It is to be understood that both the foregoing general description and the following detailed description are exemplary and explanatory only and are not restrictive of the invention, as claimed.

### BRIEF DESCRIPTION OF THE DRAWINGS

FIG. 1 illustrates a schematic diagram of an exemplary vehicle equipped with a LiDAR system, according to embodiments of the disclosure.

FIG. 2 illustrates a block diagram of an exemplary LiDAR system according to embodiments of the disclosure.

FIG. 3 illustrates a schematic diagram of an active temperature control assembly for a LiDAR system, according to embodiments of the disclosure.

FIG. 4 illustrates a schematic diagram of an active temperature control assembly for a LiDAR system, according to embodiments of the disclosure.

FIG. 5 is a flow chart illustrating an example of an active temperature control process for a LiDAR system, according to embodiments of the disclosure.

### DETAILED DESCRIPTION

Reference will now be made in detail to the exemplary embodiments, examples of which are illustrated in the accompanying drawings. Wherever possible, the same reference numbers will be used throughout the drawings to refer to the same or like parts.

In the present disclosure, the fast axis is parallel to the z axis, the slow axis is parallel to the y axis, and the optical axis is parallel to the x axis. The z axis (e.g., the vertical axis/direction) can be perpendicular to the x-y plane (e.g., the horizontal/lateral plane), and the x-axis and the y axis can be perpendicular to each other. The x-axis’ direction and the y axis direction can each be referred to as a lateral direction.

A LiDAR system may use a transmitter subsystem that transmits pulsed light beams (e.g., infrared light beam), and a receiver subsystem that receives the returned pulsed light beam and detects objects (e.g., people, animals, and automobiles) and environmental features (e.g., trees and building structures). A LiDAR system carried by a vehicle (e.g., an automobile or an unmanned aerial vehicle) may be used to determine the vehicle’s relative position, speed, and direction with respect to other objects or environmental features, and thus may, in some cases, be used for autonomous driving, auto-piloting, driving assistance, parking assistance, collision avoidance, and the like.

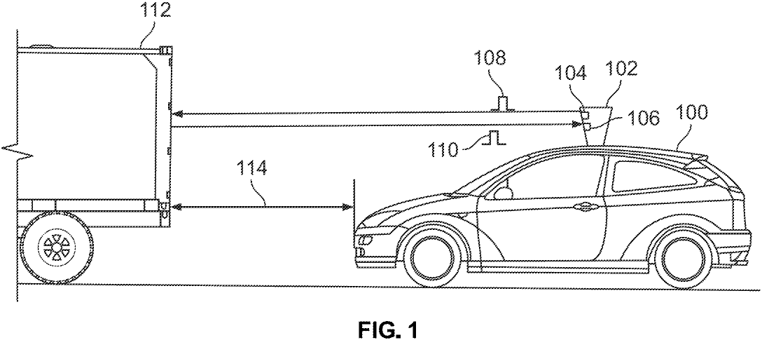

FIG. 1 illustrates a schematic diagram of an exemplary vehicle 100 equipped with a LiDAR system 102, which is mounted to the body 100 using any suitable mounting mechanisms, according to embodiments of the disclosure. The LiDAR system 102 allows the vehicle 100 to perform object detection and ranging in the surrounding environment and based on the object detection and ranging, the vehicle 100 may automatically maneuver to avoid a collision with an object in the environment. The LiDAR system 102 may include a transmitter 104 and a receiver 106. The transmitter 104 transmits light pulses 108 at various directions at different times according to a suitable scanning pattern, while receiver 106 detects the returned light pulses 110 that are reflected by one or more objects or areas. The LiDAR system 102 may detect an object and a distance of the object based on the returned light pulses 110 and the time of flight of a light pulse 110 from transmission to reception. Each area on a detected object may be represented by a data point that is associated with a 2-D or 3-D direction and distance with respect to LiDAR system 102.

In FIG. 1, for example, the LiDAR system 102 may transmit a light pulse 108 in a direction directly in front of the vehicle 100 at time T1 and receive a returned light pulse 110 that is reflected by an object 112 at time T2. Based on the detection of the light pulse 110, the LiDAR system 102 may determine that the object 112 (e.g., another vehicle) is directly in front of vehicle 100. In addition, based on the time of flight or difference between T1 and T2, LiDAR system 102 may determine a distance 114 between the vehicle 100 and the object 112.

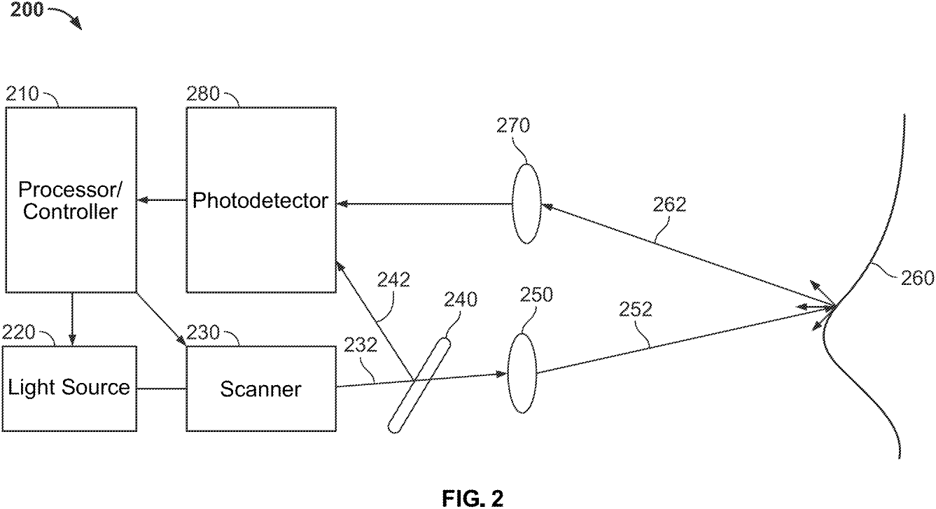

FIG. 2 illustrates a block diagram of an exemplary LiDAR system 102 having the transmitter 104 and the receiver 106 according to certain embodiments. The transmitter 104 may include a light source 220, a scanner 230 for scanning an output light beam 232 from the light source 220, a controller 210 for controlling the light source 220 and a transmitter lens 250 for transmitting light pulse 252. The light source 220 may include, for example, a laser diode or other optical sources. The receiver 106 may include a receiver lens 270, a photodetector 280. The reflected beam 262 from target 260 may be collected by receiver lens 270 and directed to photodetector 280. The photodetector 280 may include a detector having a working wavelength comparable with the wavelength of light source 220. The controller 210 controls the operations of the light source 220, the scanner 230, and the photodetector 280, and may analyze measurement results based on the control signals for the light source 220 and the scanner 230, and the signals detected by the photodetector 280.

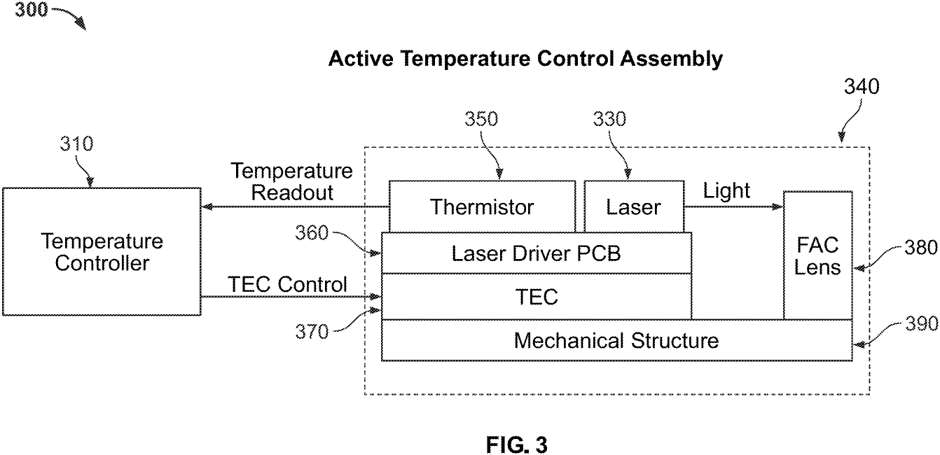

FIG. 3 illustrates a schematic of an active temperature control assembly 300 for a LiDAR system that includes a temperature controller 310 which may perform active temperature control of the laser module 340. Controller 310 may be similar to controller 210 of FIG. 2. LiDAR systems may operate over a wide range of ambient temperatures, since LiDAR systems are mounted to autonomous driving vehicles that are driven in both hot and cold climates. This ambient temperature variation causes the laser wavelength to vary in a large range, since laser wavelength is highly dependent on the operating ambient temperature. Ideally, the temperature of the laser emitter should be kept within a narrow range or a predetermined operating temperature to limit the laser wavelength to a narrow range, which allows for a narrow band filter to be used at the receiver 270 of the LiDAR system 102 in FIG. 2, which provides the benefit of a higher SNR, since less background light is received.

For example, the active temperature control assembly 300 in FIG. 3 may be used to stabilize the wavelength of the light source 330 over the large ambient operating temperature range of a LiDAR system by integrating a thermistor 350 for temperature readout and an active thermal control element 370, i.e., a Thermoelectric Cooler (TEC), with the laser module 340 to stabilize the temperature of a light source 330. As shown in FIG. 3, the light source 330 emits a light beam that is aligned by the optical lens 380. The light source 330 may be an emitter laser diode and the optical lens 380 may be a Fast-Axis Collimator lens (FAC) lens. The emitter laser diode may be packaged or embedded in a laser chip 360 and may include a printed circuit board (PCB) on which the laser diode 330 is mounted.

That is, the temperature controller 310 receives a readout temperature T0 of the laser chip 360 from the thermistor 350 at time to and compares the readout temperature T0 to a desired operating temperature Td. Based on the comparison, the controller 310 adjusts the temperature of the TEC element 370 accordingly. For example, if T0 is greater than Td, then the controller adjusts the temperature of the TEC element 370 lower and visa versa. At time t1, the controller 310 receives an updated readout temperature T1 from the thermistor 350 and compares it to the desired operating temperature Td. The controller 310 then further adjusts the temperature of the TEC element 370 as needed. This feedback control loop process is then repeated to regulate the temperature of the TEC element 370 based on the readout temperatures of the thermistor 350.

Then, since the TEC element 370 is in thermal contact with the laser chip 360, the laser emitter 330 is heated or cooled by the TEC element 370 to the desired operating temperature Td, which stabilizes the laser wavelength to a narrow range. That is, the temperature controller 310 uses the electronic feedback loop shown by the signal lines in FIG. 3 to control the temperature of the TEC element 370 based on the readout temperatures from the thermistor 350, which in turn controls the temperature of the laser 330.

The TEC element 370 is capable of heating or cooling the laser chip 360 by 60° C. or more from the ambient temperature. Therefore, while the laser chip 360 can be heated or cooled to a desired operating temperature, since it is in thermal contact with the TEC 370 element, an optical lens 380, i.e., Fast Axis Collimator (FAC) lens, of the laser module 340, is not in thermal contact with the TEC element 370 and therefore remains at or near the ambient temperature. That is, as shown in FIG. 3, the FAC lens 380 is mounted on the mechanical structure 390 by any suitable mounting mechanism. This temperature difference or delta between the controlled operating temperature of the laser chip 360 and the ambient operation temperature of FAC lens 380 may cause different thermal expansion amounts for the laser emitter 330 and the FAC lens 380, which causes the heights of the laser emitter 330 and the FAC lens 380 to shift by different amounts, thereby degrading the optical alignment between the laser emitter 330 and the FAC 380 lens in the LiDAR system.

In other words, while the active temperature control assembly 300 in FIG. 3 may be suitable for keeping the laser wavelength in a narrow band by controlling the temperature of the TEC element 370 based on the readout temperature of the laser chip 360, a temperature delta is created between the laser 330 and the FAC lens 380, since the FAC lens 380 is not subject to active temperature control by the TEC element 370 and therefore remains at or near the ambient temperature. This temperature difference leads to different thermal expansion amounts for the laser emitter 330 and the FAC lens 380 which causes the heights of the laser emitter 330 and the FAC lens 380 to shift by different amounts in the Z axis, thereby degrading the optical alignment between the laser emitter 330 and the optical lens 380 in the LiDAR system.

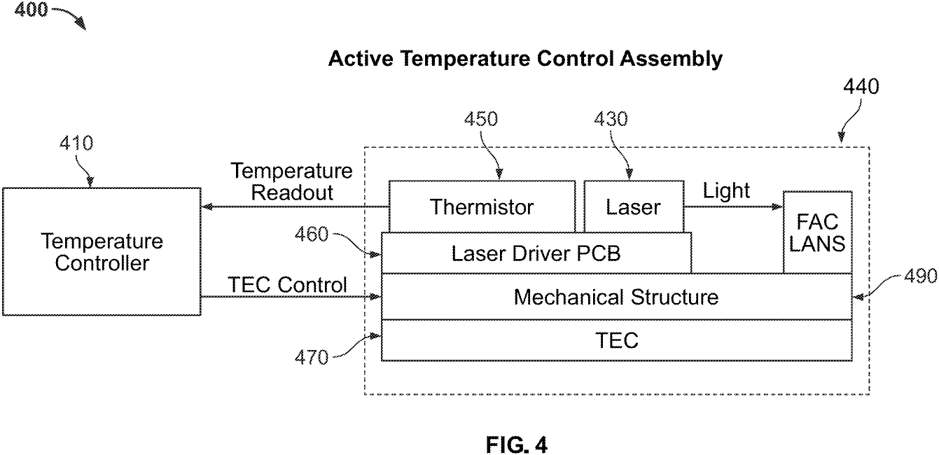

FIG. 4 illustrates a schematic diagram of an active temperature control assembly 400 for a LiDAR system that includes a temperature controller 410 which may perform temperature control of the laser module 440 according to an embodiment of the invention. The active control temperature assembly 400, as shown in FIG. 4, is similar to the active control temperature assembly 300, as shown in FIG. 3 in that the temperature controller 410 uses the electronic feedback loop shown by the signal lines in FIG. 4 to control the temperature of the TEC element 470 based on the readout temperature from the thermistor 450.

The active temperature assembly 400 of FIG. 4 is configured to have the active thermal control element (TEC element) 470 provide thermal control to both the laser emitter 430 and the FAC lens 480 such that the laser emitter 430 and the optical lens 480 are controlled by the TEC element 470 to be at (or near) the same operating temperature over a large range of different ambient temperatures for the LiDAR system. That is, controlling the laser emitter 430 and the FAC lens 480 to be at the same operating temperature causes the thermal expansion amounts for the laser emitter 430 and the optical lens 480 to track each other, which minimizes the optical misalignment over a large range of ambient temperatures for the LiDAR system.

As illustrated in FIG. 4, the laser chip 460 and the FAC lens 480 are both fixed or mounted, by any suitable mounting mechanism, onto an upper surface of the shared mechanical structure 490. As further illustrated in FIG. 4, the mechanical structure 490 is fixed, i.e., by bonding or any other suitable fixing mechanism, to the upper surface of the TEC element 470 and is heated or cooled to the controlled temperature of the TEC element 470, since it is in thermal contact with the TEC element 470. It is understood that the mechanical structure 490 is formed of thermally conductive material, for example, Cu, Au, etc. That is, the TEC element 470 is in thermal contact with the mechanical structure 490 and the mechanical structure 490 is in thermal contact with both the laser chip 460 and the FAC lens 480. In this way, the active temperature control of the TEC element 470 is provided to regulate the temperature of both the laser chip 460 and the FAC lens 480 by the thermally conductive shared mechanical structure 490 in FIG. 4.

Therefore, in the active temperature control assembly 400, since the temperature of both the laser emitter 430 and tire FAC lens 480 can be controlled by the same TEC element 470 via the thermally conductive shared mechanical structure 490, the laser chip 460 and the FAC lens 480 are subject to the same thermal expansion amounts, which minimizes or eliminates any optical misalignment in the z-axis or height direction between the laser emitter 430 and the FAC lens 480. Thus, in addition to providing temperature control to the laser chip 460, which provides the benefit of a higher SNR, as previously discussed, the active control temperature assembly 400 of FIG. 4 provides the same temperature control to the FAC lens 480 as the laser chip 460, which minimizes the optical misalignment between the laser emitter 430 and the FAC lens 480 due to thermal expansion. That is, the thermal expansions for the laser emitter 430 and the FAC lens 480 will track each other over a large range of ambient operating temperature for the LiDAR system and minimize the optical misalignment between the laser emitter 430 and the FAC lens 480 in the height direction.

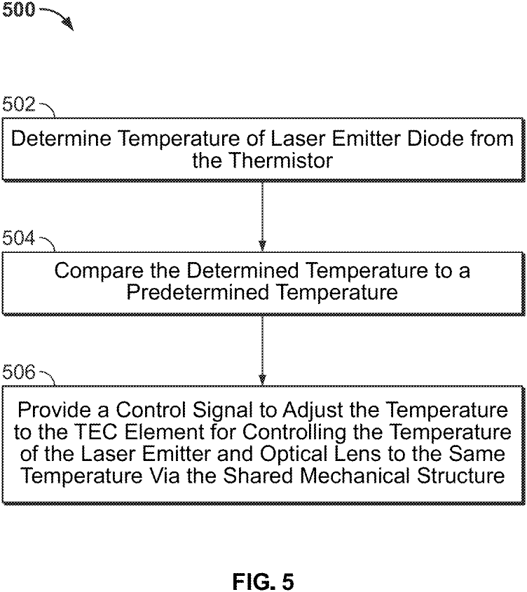

FIG. 5 is a flow chart 500 illustrating an example of a process performed by the temperature controller 410 of a LiDAR system to adjust the temperature of the active thermal control element 470 in order to regulate the temperature of the both the laser emitter 430 and the optical lens 480 to the same temperature over a large range of ambient temperatures according to certain embodiments of the present disclosure. For example, an electronic feedback loop between the laser chip 460, the active thermal control element 370 and the temperature controller 410 using the signal lines shown in FIG. 4 is used to control the temperature of the laser emitter 430 and the optical lens 480.

At step S502, the temperature of the laser emitter 460 is determined. The actual temperature of the emitting laser diode 430 is measured by a thermistor 450 that is incorporated into its laser chip 460. This thermistor signal, which is typically in the form of a resistance value, is transmitted to the temperature controller 410 wherein a resistance-to-temperature conversion using, for example, the Steinhart-Hart equation is performed by the temperature controller 410.

At step S504, the temperature controller 410 compares the determined temperature to a predetermined set point operating temperature for the emitting laser diode 430. Based on this comparison, in step S506, the temperature controller 410 provides a (TEC) control signal, as shown in FIG. 4, to the TEC element 470 to adjust the temperature of the TEC element 47 for controlling the temperature of the laser emitter 430 and optical lens 480 to the same temperature via the shared thermally conductive mechanical structure 490.

That is, if the emitting laser diode 430 is operating at a temperature higher than a desired set point operating temperature, the temperature controller 410 provides the control signal to adjust the temperature of the TEC element 470 lower. Conversely, if the emitting laser diode 430 is operating at a temperature lower than the set point operating temperature, the temperature controller 410 provides a control signal to adjust the temperature of the TEC element 470 higher. As discussed above, the TEC element 470 is tied or fixed to the bottom surface of the shared thermally conductive mechanical structure 490, which is configured to control the temperatures of the emitting laser diode 430 and the FAC lens 480 to the same temperature over a large range of ambient temperatures for the LiDAR system.

The processing depicted in FIG. 5 may be implemented in software (e.g., code, instructions, program) executed by one or more processing units (e.g., processors, cores) of the respective systems, hardware, or combinations thereof. For example, the operations in flow chart 500 may be performed by processor, controller 410 described above. The software may be stored on a non-transitory storage medium (e.g., on a memory device). The processing presented in FIG. 5 and described above is intended to be illustrative and non-limiting.

In the following description, for the purposes of explanation, specific details are set forth in order to provide a thorough understanding of examples of the disclosure. It will be apparent that various examples may be practiced without these specific details. The ensuing description provides examples only, and is not intended to limit the scope, applicability, or configuration of the disclosure. Rather, the ensuing description of the examples will provide those skilled in the art with an enabling description for implementing an example. It should be understood that various changes may be made in the function and arrangement of elements without departing from the spirit and scope of the disclosure as set forth in the appended claims. The figures and description are not intended to be restrictive. Circuits, systems, networks, processes, and other components may be shown as components in block diagram form in order not to obscure the examples in unnecessary detail. In other instances, well-known circuits, processes, algorithms, structures, and techniques may be shown without unnecessary detail in order to avoid obscuring the examples. The teachings disclosed herein can also be applied to various types of applications such as mobile applications, non-mobile application, desktop applications, web applications, enterprise applications, and the like. Further, the teachings of this disclosure are not restricted to a particular operating environment (e.g., operating systems, devices, platforms, and the like) but instead can be applied to multiple different operating environments.

Furthermore, examples may be implemented by hardware, software, firmware, middleware, microcode, hardware description languages, or any combination thereof. When implemented in software, firmware, middleware or microcode, the program code or code segments to perform the necessary tasks (e.g., a computer-program product) may be stored in a machine-readable medium. A processor(s) may perform the necessary tasks.

Also, it is noted that individual examples may be described as a process which is depicted as a flowchart, a flow diagram, a data flow diagram, a structure diagram, or a block diagram. Although a flowchart may describe the operations as a sequential process, many of the operations may be performed in parallel or concurrently. In addition, the order of the operations may be re-arranged. A process is terminated when its operations are completed, but could have additional steps not included in a figure. A process may correspond to a method, a function , a procedure, a subroutine, a subprogram, etc. When a process corresponds to a function, its termination may correspond to a return of the function to the calling function or the main function.

Where components are described as being “configured to” perform certain operations, such configuration may be accomplished, for example, by designing electronic circuits or other hardware to perform the operation, by programming or controlling electronic circuits (e.g., microprocessors, or other suitable electronic circuits) to perform the operation, or any combination thereof.

The word “example” or “exemplary” is used herein to mean “serving as an example, instance, or illustration.” Any embodiment or design described herein as “exemplary” or “example” is not necessarily to be construed as preferred or advantageous over other embodiments or designs.

The digital signal processing circuit may include a special-purpose processing circuit or a general-purpose processor, such as one or more CPUs, microcontrollers (MCUs), digital signal processors (DSPs), ASIC’s, programmable logic devices, or the like, with supporting hardware (e.g., memory), firmware, and/or software, as would be appreciated by one of ordinary skill in the art.

Numerous specific details are set forth herein to provide a thorough understanding of the claimed subject matter. However, those skilled in die art will understand that the claimed subject matter may be practiced without these specific details. In other instances, methods, apparatuses, or systems that would be known by one of ordinary skill have not been described in detail so as not to obscure claimed subject matter. The various embodiments illustrated and described are provided merely as examples to illustrate various features of the claims. However, features shown and described with respect to any given embodiment are not necessarily limited to the associated embodiment and may be used or combined with other embodiments that are shown and described. Further, the claims are not intended to be limited by any one example embodiment.

While the present subject matter has been described in detail with respect to specific embodiments thereof, it will be appreciated that those skilled in the art, upon attaining an understanding of the foregoing may readily produce alterations to, variations of, and equivalents to such embodiments. Accordingly, it should be understood that the present disclosure has been presented for purposes of example rather than limitation, and does not preclude inclusion of such modifications, variations, and/or additions to the present subject matter as would be readily apparent to one of ordinary skill in the art. Indeed, the methods and systems described herein may be embodied in a variety of other forms, furthermore, various omissions, substitutions and changes in the form of the methods and systems described herein may be made without departing from the spirit of the present disclosure. The accompanying claims and their equivalents are intended to cover such forms or modifications as would fall within the scope and spirit of the present disclosure.

Although the present disclosure provides certain example embodiments and applications, other embodiments that are apparent to those of ordinary skill in the art, including embodiments which do not provide all of the features and advantages set forth herein, are also within the scope of this disclosure. Accordingly, the scope of the present disclosure is intended to be defined only by reference to the appended claims.

Unless specifically stated otherwise, it is appreciated that throughout this specification discussions utilizing terms such as “processing,” “computing,” “calculating,” “determining,” and “identifying” or the like refer to actions or processes of a computing device, such as one or more computers or a similar electronic computing device or devices, that manipulate or transform data represented as physical electronic or magnetic quantities within memories, registers, or other information storage devices, transmission devices, or display devices of the computing platform.

The system or systems discussed herein are not limited to any particular hardware architecture or configuration. A computing device can include any suitable arrangement of components that provide a result conditioned on one or more inputs. Suitable computing devices include multi-purpose microprocessor-based computer systems accessing stored software that programs or configures the computing system from a general purpose computing apparatus to a specialized computing apparatus implementing one or more embodiments of the present subject matter. Any suitable programming, scripting, or other type of language or combinations of languages may be used to implement the teachings contained herein in software to be used in programming or configuring a computing device.

Conditional language used herein, such as, among others, “can,” “could,” “might,” “may,” “e.g.,” and the like, unless specifically stated otherwise, or otherwise understood within the context as used, is generally intended to convey that certain examples include, while other examples do not include, certain features, elements, and/or steps. Thus, such conditional language is not generally intended to imply that features, elements and/or steps are in any way required for one or more examples or that one or more examples necessarily include logic for deciding, with or without author input or prompting, whether these features, elements and/or steps are included or are to be performed in any particular example.

The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list. The use of “adapted to” or “configured to” herein is meant as open and inclusive language that does not foreclose devices adapted to or configured to perform additional tasks or steps. Additionally, the use of “based on” is meant to be open and inclusive, in that a process, step, calculation, or other action “based on” one or more recited conditions or values may, in practice, be based on additional conditions or values beyond those recited. Similarly, the use of “based at least in part on” is meant to be open and inclusive, in that a process, step, calculation, or other action “based at least in part on” one or more recited conditions or values may, in practice, be based on additional conditions or values beyond those recited. Headings, lists, and numbering included herein are for ease of explanation only and are not meant to be limiting.

It will be apparent to those skilled in the art that various modifications and variations can be made to the disclosed system and related methods. Other embodiments will be apparent to those skilled in the art from consideration of the specification and practice of the disclosed system and related methods.

It is intended that the specification and examples be considered as exemplary only, with a true scope being indicated by the following claims.

What is claimed is:

1. An assembly for a light detection and ranging (LiDAR) system, comprising:
a light source configured to provide a light beam;
a light collimator lens configured to collimate the light beam;
an active thermal control element having an upper surface;
a thermally conductive mechanical structure fixed to the upper surface of the active thermal control element, the mechanical structure being in thermal contact with the light source, the light collimator lens and the active thermal control element;
a temperature sensor configured to detect the temperature of the light source; and
a temperature controller configured to receive the detected temperature from the light source and in response control the temperature of the active thermal control element.

2. The assembly for a light detection and ranging (LiDAR) system according to claim 1, wherein the temperature sensor is a thermistor.

3. The assembly for a light detection and ranging (LiDAR) system according to claim 2, wherein the active thermal control element comprises a thermoelectric cooler (TEC).

4. The assembly for a light detection and ranging (LiDAR) system according to claim 1, wherein the light collimator lens is a fast-axis collimating lens.

5. The assembly for a light detection and ranging (LiDAR) system according to claim 1, wherein the light source is fixed to an upper surface of the thermally conductive mechanical structure.

6. The assembly for a light detection and ranging (LiDAR) system according to claim 1, wherein the light collimator lens is fixed to an upper surface of the thermally conductive mechanical structure.
